(19) United States
(12) Patent Application Publication
(10) Pub. No.: US 2016/0313847 A1
(43) Pub. Date: Oct. 27, 2016

(54) SENSING DEVICE

(71) Applicant: IMAGE MATCH DESIGN INC., HSINCHU (TW)

(72) Inventors: YEN-KUO LO, TAINAN CITY (TW); CHIA-HUA YEH, HSINCHU CITY (TW)

(21) Appl. No.: 14/985,337

(22) Filed: Dec. 30, 2015

(30) Foreign Application Priority Data
Apr. 21, 2015 (TW) 104112655

(51) Int. Cl. G06F 3/041; G06F 1/16; H05K 1/02; G06F 3/044

(52) U.S. Cl. CPC G06F 3/0416; G06F 3/044; G06F 1/16; H05K 1/0296

(57) ABSTRACT

A sensing device for detecting a capacitance in response to a touch event of an object is provided. The sensing device includes a first conductive component and a second conductive component. The first conductive component is formed in a first patterned conductive layer, and has a first sidewall and a second sidewall. The second conductive component is formed in the first patterned conductive layer, and has a first sidewall opposed to the first sidewall of the first conductive component, and a second sidewall opposed to the second sidewall of the first conductive component. The first sidewalls of the first conductive component and the second conductive component define a first capacitance therebetween, and the second sidewalls of the first conductive component and the second. conductive component define a second capacitance therebetween.

### TECHNICAL FIELD

The present disclosure is generally related to an electronic device and, more particularly, to a sensing device.

### BACKGROUND

These days, touch devices are widely applied to electronic devices, for example, smart phones and laptop computers. With touch devices, users can easily operate on smart phones or laptop computers. Sensitivity of some existing capacitive-type touch devices is not desirable due to stray to capacitance between electrodes. To address the issue, some existing approaches increase the distance between the electrodes so as to reduce the stray capacitance and thereby enhance the sensitivity. However, such approaches inevitably lead to additional area cost. In view of this, there is a need to provide a new sensing device that can provide desirable sensitivity without sacrificing the area.

### SUMMARY

Embodiments of the present disclosure provide a sensing device for detecting a capacitance in response to a touch event of an object. The sensing device includes a first conductive component and a second conductive component. The first conductive component is formed in a first patterned conductive layer, and has a first sidewall and a second sidewall. The second conductive component is formed in the first patterned conductive layer, and has a first sidewall opposed to the first sidewall of the first conductive component, and a second sidewall opposed to the second sidewall of the first conductive component. The first sidewalls of the first conductive component and the second conductive component define a first capacitance therebetween, and the second sidewalls of the first conductive component and the second conductive component define a second capacitance therebetween.

In an embodiment, the first capacitance and the second capacitance are connected in parallel with respect to the capacitance detected during the touch event.

In another embodiment, the first sidewall and the second sidewall of the first conductive component form a recess, and at least a portion of the second conductive component is positioned in the recess.

in yet another embodiment, the first capacitance and the second capacitance are connected in parallel between an input and an output of an amplifier.

In still another embodiment, an equivalent capacitance between the input and the output of the amplifier is equal to a sum of the first capacitance and the second capacitance.

In yet still another embodiment, a voltage value at the output of the amplifier is a function of the equivalent capacitance.

In a further embodiment, the voltage value at the output of the amplifier and the equivalent capacitance have a relationship below.

$$\frac{Vout}{Vin} = - \frac{{C}_{F}}{( {C}_{1} + {C}_{2} )}$$

where Vout represents the voltage value at the output of the amplifier, and Vin represents a voltage value of a trigger signal input to the sensing device, C₁ represents the first capacitance, C₂ represents the second capacitance, and C_{F} represents the capacitance detected during the touch event.

In further another embodiment, the first conductive component further includes a third sidewall, and the second conductive component further includes a third sidewall opposed to the third sidewall of the first conductive component. The third sidewalls of the first conductive component and the second conductive component define a third capacitance therebetween.

In still further another embodiment, a normal direction of the third sidewall of the second conductive component is in parallel with a normal direction of the second sidewall of the second conductive component.

In yet still further another embodiment, the first sidewall, the second sidewall and the third sidewall of the first conductive component form a recess, and the second conductive component is positioned in the recess.

In a yet further embodiment, the first sidewall, the second sidewall and the third sidewall of the first conductive component form a recess, and a portion of the second conductive component is positioned outside the recess.

In a still yet embodiment, the first capacitance, the second capacitance and the third capacitance are coupled between an input and an output of an amplifier.

In a further yet embodiment, the second conductive component further includes a surface, and the sensing device further includes a third conductive component. The third conductive component is formed in a second patterned conductive layer different from the first patterned conductive layer, and includes a surface opposed to the surface of the second conductive component. The surface of the third conductive component and the surface of the second conductive component define a fourth capacitance therebetween.

In a still further yet embodiment, the first capacitance and the second capacitance are coupled in parallel between an input of an amplifier and the fourth capacitance, and the parallel connected first capacitance and. second capacitance are serially connected with the fourth capacitance between the input and an output of the amplifier.

In a still yet further embodiment, the equivalent capacitance between the input and the output of the amplifier is determined by the first capacitance and the second capacitance.

In an additional embodiment, a voltage value at the output of the amplifier is a function of the equivalent capacitance.

In a further embodiment again, the voltage value at the output of the amplifier and the equivalent capacitance have a relationship below.

$$\frac{Vout}{Vin} = - \frac{{C}_{F}}{\frac{( {C}_{1} + {C}_{2} ) \times {C}_{4}}{( {C}_{1} + {C}_{2} ) + {C}_{4}}} = - \frac{{C}_{F} \times [ ( {C}_{1} + {C}_{2} ) + {C}_{4} ]}{( {C}_{1} + {C}_{2} ) \times {C}_{4}}$$

where Vout represents the voltage value at the output of the amplifier, Vin represents a voltage value of a trigger signal input to the sensing device, C₁ represents the first capacitance, C₂ represents the second capacitance, C₄ represents the fourth capacitance, and C_{F} represents the capacitance detected during the touch event.

In an embodiment, the second conductive component further includes a surface, and the sensing device further includes a third conductive component. The third conductive component is formed in a second patterned conductive layer different from the first patterned conductive layer, and includes a surface opposed to the surface of the second conductive component. The surface of the third conductive component and the surface of the second conductive component define a fourth capacitance therebetween.

In an embodiment, the first capacitance and the second capacitance are coupled in parallel between an input of an amplifier and the fourth capacitance, and the parallel connected first capacitance and second capacitance are serially connected with the fourth capacitance between the input and an output of the amplifier.

The sensing device of the invention is less susceptible to interference. Moreover, given the same sizes of conductive components, sensitivity can be increased by adjusting the relative positions of conductive components without incurring area cost.

The foregoing has outlined, rather broadly the features and technical advantages of the present invention in order that the detailed description of the invention that follows may be better understood. Additional features and advantages of the invention will be described hereinafter. It should. be appreciated by those skilled in the art that the conception and specific embodiments disclosed may be readily utilized as a basis for modifying or designing other structures or processes for carrying out the same purposes of the present invention. It should also be realized by those skilled, in the art that such equivalent constructions do not depart from the spirit and scope of the invention as set forth in the appended claims.

### BRIEF DESCRIPTION OF THE DRAWINGS

Details of one or more embodiments of the disclosure are set forth in the accompanying drawings and the description below. Other features and advantages of the disclosure will be apparent from the description, drawings and claims.

FIG. 1 is a top view of a sensing device, in accordance with an exemplary embodiment of the present disclosure.

FIG. 2A is a schematic perspective diagram of a sensing unit in the sensing device shown in FIG. 1, in accordance with an exemplary embodiment of the present disclosure.

FIG. 2B is a circuit diagram of an amplifier circuit, in a small-signal model, of the sensing device shown in FIG. 2A.

FIG. 2C is a top view of conductive components shown in FIG. 7A.

FIG. 2D is a diagram showing an exemplary case of two electrode plates for comparison with the conductive components in FIG. 2C.

FIG. 3 is a diagram of a sensing device, in accordance with an exemplary embodiment of the present disclosure.

FIG. 4A is a diagram of a sensing device, in accordance with an exemplary embodiment of the present disclosure.

FIG. 4B is a circuit diagram of an amplifier circuit, in a small-signal mode, of the sensing device as shown in FIG. 4A.

FIG. 5 is a diagram of a sensing device, in accordance with an to exemplary embodiment of the present disclosure.

### DETAIL DESCRIPTION

In order to make the disclosure completely comprehensible, detailed steps and structures are provided in the following description. Obviously, implementation of the disclosure does not limit special details known by persons skilled in the art. In addition, known structures and steps are not described in detail, so as not to limit the disclosure unnecessarily. Preferred embodiments of the disclosure will be described below in detail. However, in addition to the detailed description, the disclosure may also be widely implemented in other embodiments. The scope of the disclosure is not limited to the detailed description, and is defined by the claims.

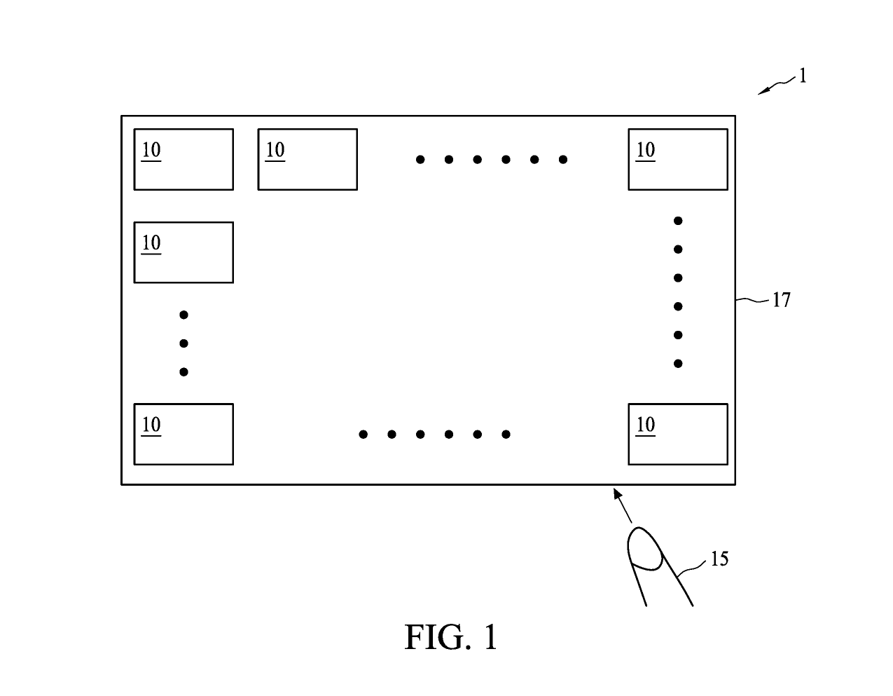

FIG. 1 is a top view of a sensing device 1, in accordance with an exemplary embodiment of the present disclosure. The sensing device 1. may be mounted on an electronic device such as a smart phone, laptop computer and personal digital assistant. Referring to FIG. 1, the sensing device 1 includes a sensing array of sensing units 10, which are covered by a transparent protection layer 17. The sensing units 10 are configured to sense a touch event of an object 15, such as a finger or a touch pen, on the sensing device 1 through the transparent protection layer 17.

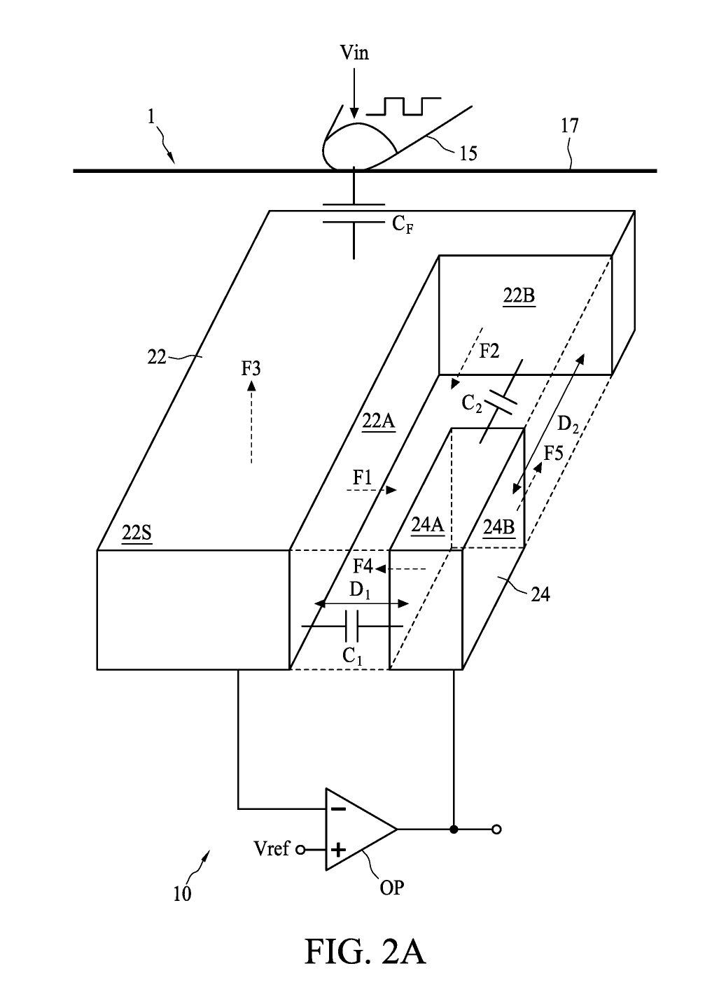

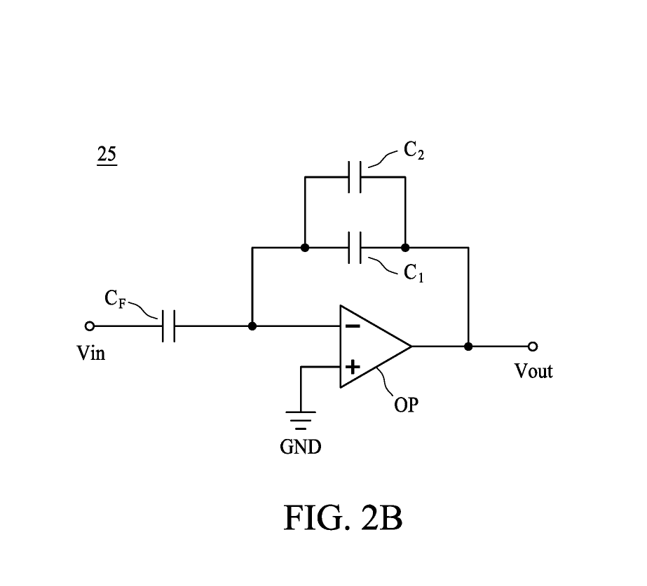

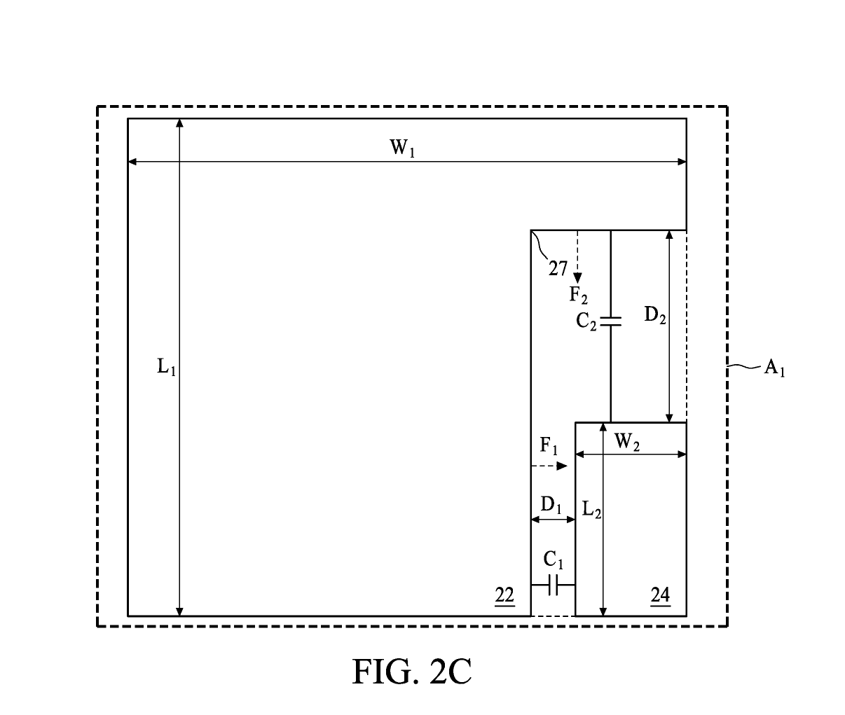

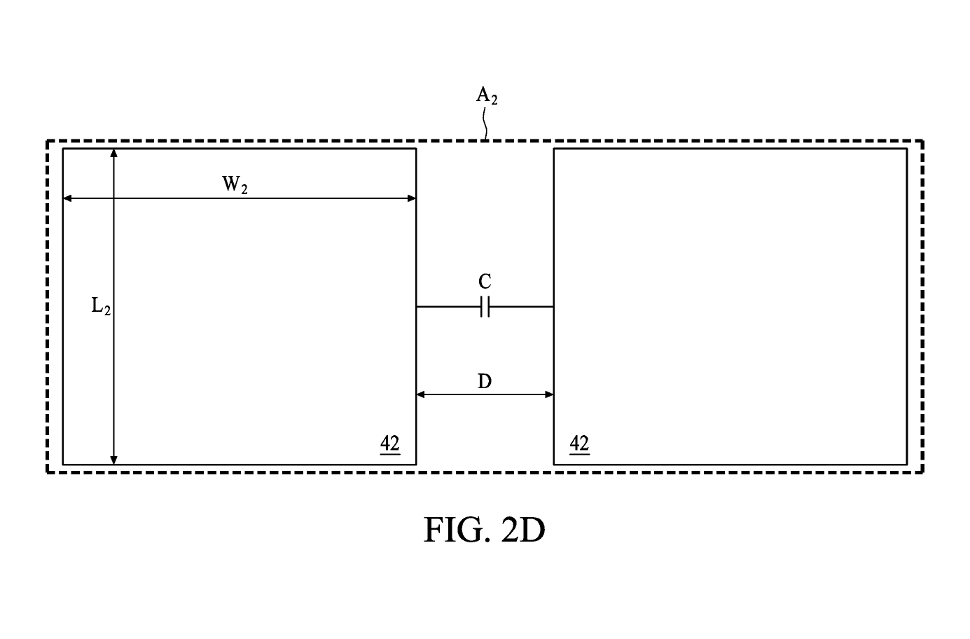

FIG. 2A is a schematic perspective diagram of a sensing unit 10 in the sensing device 1 shown in FIG. 1, in accordance with some embodiments of the present invention. Referring to FIG. 2A, for convenience of illustration, only one sensing unit is shown in FIG. 2A. The sensing unit 10 includes an amplifier OP, and a first conductive component 22 and a second conductive component 24 in a first patterned conductive layer. In some embodiments, the first patterned conductive layer is a metal layer that can be formed in a semiconductor manufacturing process. Moreover, the metal layer is etched to form the first patterned conductive layer and define the first conductive component 22 and the second conductive component 24. The first conductive component 22 and the second conductive component 24 are separated by dielectric materials.

The first conductive component 22 has a first sidewall 22A, a second sidewall 22B and a surface 22S. The first sidewall 22A, the second sidewall 22B and the surface 22S are immediately adjacent to each other. For convenience, it is assumed that the first sidewall 22A, the second sidewall 22B and the surface 22S are planar surfaces. Moreover, the first sidewall 22A has a surface normal in a direction F1, the second sidewall 22B has a surface normal in a direction F2, and the surface 22S has a surface normal in a direction F3. The surface 22S faces the object 15 in the normal direction F3 during a touch event. In some embodiments, the normal directions F1, F2 and F3 are substantially orthogonal to each other.

The second conductive component 24 has a first sidewall 24A and a second sidewall 24B. The first sidewall 24A and the second sidewall 24B are immediately adjacent to each other. For convenience, it is assumed that the first sidewall 24A and the second sidewall 24B are planar surfaces. Moreover, the first sidewall 24A has a surface normal in a direction F4, which is substantially opposite to the normal direction F1. The first sidewall 24A is opposed to the first sidewall 22A of the first conductive component 22, and spaced apart from the first sidewall 22A of the first conductive component 22 by a distance D₁. The first sidewall 24A of the second conductive component 24 and the first sidewall 22A of the first conductive component 22 define a first capacitance C₁. Since the distance D₁ is a factor of the first capacitance C₁, by adjusting the distance D₁ in a layout design stage, the first capacitance C₁ is adjusted. The first capacitance C₁ decreases as the distance D₁ increases, and vice versa.

Furthermore, the second sidewall 24B has a surface normal in a direction F5, which is substantially opposite to the normal direction F2. The second sidewall 24B is opposed to the second sidewall 22B of the first conductive component 22, and spaced apart from the second sidewall 22B of the first conductive component 22 by a distance D₂. The second sidewall 24B of the second conductive component 24 and the second sidewall 22B of the first conductive component 22 define a second capacitance C₂. Since the distance D₂ is a factor of the second capacitance C₂, by adjusting the distance D₂ in a layout design stage, the second capacitance C₂ is adjusted. The second capacitance C₂ decreases as the distance D₂ increases, and vice versa.

The amplifier OP includes a first input terminal (non-inverting input terminal; “+” terminal), a second input terminal (inverting input terminal; “−” terminal) and an output terminal. The first input terminal is coupled to a reference voltage Vref. The second input terminal is coupled to the first conductive component 22. The output terminal is coupled to the second conductive component 24.

In operation, the sensing device 1 is configured to, in response to a touch event of the object 15 on the sensing device 1, detect a capacitance C_{F} in the normal direction F3. Specifically, in operation, the first conductive component 22 is configured to, in response to the touch event of the object 15 on the sensing device 1, detect the capacitance C_{F} in the normal direction F3.

For convenience, a same reference numeral or label is used to refer to a capacitance or, when appropriate, its capacitor throughout the disclosure, and vice versa. For example, while the reference label “C_{F}” as above mentioned refers to a capacitance, it may represent a capacitor of the capacitance.

During the touch event, a trigger signal Vin is input to the sensing device 1 via the object 15 in response to the touch event, and is coupled to the second input terminal of the amplifier OP via the capacitor C_{F}. Moreover, during the touch event, an amplifier circuit is formed by the object 15, the first conductive component 22, the second conductive component 24 and the amplifier OP.

FIG. 2B is a circuit diagram of an amplifier circuit 25, in a small-signal model, of the sensing device 1 shown in FIG. 2A. Referring to FIG. 2B, in a small-signal analysis, the reference voltage Vref is deemed as a reference ground GND. Thus, the first input terminal of the amplifier OP is coupled to the reference ground GND. For convenience, in the following text, each of “C₁” and “C₂” also refers to a capacitor. The first capacitor C₁ and the second capacitor C₂ are coupled in parallel with each other between the second input terminal and the output terminal of the amplifier OP. Further, the first capacitor C₁ and the second capacitor C₂ are connected in parallel with respect to the capacitor C_{F} detected during the touch event. The amplifier OP receives the trigger signal Yin at the second input terminal, amplifies the trigger signal Vin and outputs a detection signal Vout at the output terminal. The detection signal Vout is the amplified trigger signal Yin. The relationship between the detection signal Vout and the trigger signal Vin can be expressed in the following equation (1).

$$\frac{Vout}{Vin} = - \frac{{C}_{F}}{( {C}_{1} + {C}_{2} )} \qquad ( 1 )$$

where C₁ represents the first capacitance, C₂ represents the second capacitance C₂, and C_{F} represents the capacitance C_{F}. Moreover, in equation (1), Vout represents a voltage value of the detection signal Vout, and Yin represents a voltage value of the trigger signal Yin. The voltage value of the detection signal Vout is substantially equal to that at the output terminal of the amplifier OP. Furthermore, (C₁+C₂) represents an equivalent capacitance between the second input terminal and the output terminal of the amplifier OP.

The absolute value of the ratio of the detection signal Vout to the trigger signal Vin represents a gain of the amplifier circuit 25. From the above equation (1), the gain of the amplifier circuit 25 is a function of the first capacitance C₁. Other things being equal, the gain of the amplifier circuit 25 decreases as the first capacitance C₁ increases, and vice versa. Likewise, the gain of the amplifier circuit 25 is a function of the second capacitance C₂. Other things being equal, the gain of the amplifier circuit 25 decreases as the second capacitance C₂ increases, and vice versa.

Moreover, from equation (1), the gain of the amplifier circuit 25 is also a function of the equivalent capacitance (C₁+C₂) between the second input terminal and the output terminal of the amplifier OP. For instance, the gain of the amplifier circuit 25 increases as the equivalent capacitance decreases. Further, the gain of the amplifier circuit 25 is positively correlated with touch sensitivity. The touch sensitivity increases as the gain of the amplifier circuit 25 increases, and vice versa.

Furthermore, the voltage value at the output terminal of the amplifier OP is a function of the equivalent capacitance (C₁+C₂) between the second input terminal and the output terminal of the amplifier OP. For instance, the voltage value at the output terminal of the amplifier OP increases as the equivalent capacitance between the second input terminal and the output terminal of the amplifier OP decreases, and vice versa.

FIG. 2C is a top view of the conductive components shown in FIG. 2A. Referring to FIG. 2C, the first sidewall 22A and the second sidewall 22B of the first conductive component 22 define a recess 27, which will be discussed below. In some embodiments, the second conductive component 24 is substantially positioned in the recess 27. In some embodiments, a portion of the second conductive component 24 is positioned outside the recess 27.

The first conductive component 22 has a length L₁ and a width W₁, both taken from their respective largest measurements. The length L₁ and the width W₁ determine a rectangular region having an area of A1. Accordingly, the area A1 of the region is the product of the length L₁ and the width W₁. For illustration, the region is shown in a dashed-line box slightly expanded beyond the area A1. The recess 27 accounts for an area substantially equal to the area A1 minus the area of the polygonal first conductive component 22.

In some embodiments, as in the present embodiment, the second conductive component 24 is positioned in the recess 27. In that case, the area occupied by the first conductive component 22 and the second conductive component 24 is smaller than the product of the length L₁ and the width W₁. The second conductive component 24 has a length L₂ and a width W₂. In an embodiment, the length L₂ is shorter than the length L₁ and the width W₂ is shorter than the width W₁. Given the distance D₁ associated with the first capacitance C₁ and the distance D₂ associated with the second capacitance C₂ being kept unchanged, the first capacitance C₁ is determined by the length L₂, and the second capacitance C₂ is determined by the width W₂.

In some embodiments, a portion of the second conductive component 24 is positioned in the recess 27, and another portion of the second conductive component 24 is positioned outside the recess 27. In that case, given the distance D₁ associated with the first capacitance C₁ and the distance D₂ associated with the second capacitance C₂ being kept unchanged, the first capacitance C₁ is determined by a portion of the length L₂ that falls within the recess 27, and the second capacitance C₂ is determined by a portion of the width W₂ that fails within the recess 27.

Assume the second conductive component 24 is initially positioned at a certain place, where the second conductive component 24 is spaced apart from the first conductive component 22 in the normal direction F₁ by the distance D₁, and in the normal direction F₂ by a distance smaller than the distance D₂. Since the distance is smaller than the distance D₂, a capacitance in the normal direction F₂ defined by the first conductive component 22 and the second conductive component 24 is greater than the second capacitance C₂. If the touch sensitivity as a result of such arrangement is lower, the touch sensitivity can be adjusted by adjusting the position of the second conductive component 24 with respect to the recess 27. For instance, the second conductive component 24 can be relocated to a position as shown in FIG. 2C. Accordingly, since the distance in the normal direction F₂ between the first conductive component 22 and the second conductive component 24 is increased, the capacitance in the normal direction F₂ defined, by the first conductive component 22 and the second conductive component 24 is decreased, resulting in an increase in the touch sensitivity of the sensing device 1.

Similarly, the touch sensitivity of the sensing device 1 could be enhanced by adjusting the distance in the normal direction F₁ between the first conductive component 22 and the second conductive component 24.

In the embodiment that the second conductive component 24 is positioned in the recess 27, since the first conductive component 22 and the second conductive component 24 form two pairs of opposed sidewalls (namely, the first sidewalls 22A and 24A, and the second sidewalls 22B and 24B), given the sizes of the first conductive component 22 and the second conductive component 24 being kept unchanged, the touch sensitivity can be enhanced by adjusting the position of the second conductive component 24 in either the normal direction F₁ or F₂ without incurring area cost.

In the embodiment that a portion of the second conductive component 24 is positioned outside the recess 27, assuming that that portion of the second conductive component 24 outside the recess 27 extends in the normal direction F₁, since the first conductive component 22 and the second conductive component 24 form two pairs of opposed sidewalls, given the sizes of the first conductive component 22 and the second conductive component 24 being kept unchanged, the touch sensitivity can be enhanced by adjusting the position of the second conductive component 24 in the normal direction F₂ without incurring area cost.

Similarly, in the embodiment that a portion of the second conductive component 24 is positioned outside the recess 27, assuming that that portion of the second conductive component 24 outside the recess 27 extends in the normal direction F₂, since the first conductive component 22 and the second conductive component 24 form two pairs of opposed sidewalls, given the sizes of the first conductive component 22 and the second conductive component 24 being kept unchanged, the touch sensitivity can be enhanced by adjusting the position of the second conductive component 24 in the normal direction F₁ without incurring area cost.

FIG. 2D is a diagram of an exemplary case of two electrode plates 42 for comparison with the conductive components in FIG. 2C. Referring to FIG. 2D, each of the electrode plates 42 has a length L₂ and a width W₂. The two electrode plates 42 are spaced apart by a distance D, and thereby define a capacitance C and certain touch sensitivity. An area A₂ needed to define the capacitance C is the sum of the areas of the electrode plates 42, i.e., two times of the product of the length L₂ and the width W₂, and the product of the distance D and the length L₂. In such exemplary arrangement, since the two electrode plates 42 form only one pair of opposed sidewalls, and define no recess, given the sizes of the two electrode plates 42 being kept unchanged, the touch sensitivity can be enhanced by increasing the distance D. However, once the distance D is increased, the area A₂ is also correspondingly increased. Thus, as compared to the sensing device 1 of the present disclosure, in order to enhance touch sensitivity, such exemplary arrangement consumes more areas.

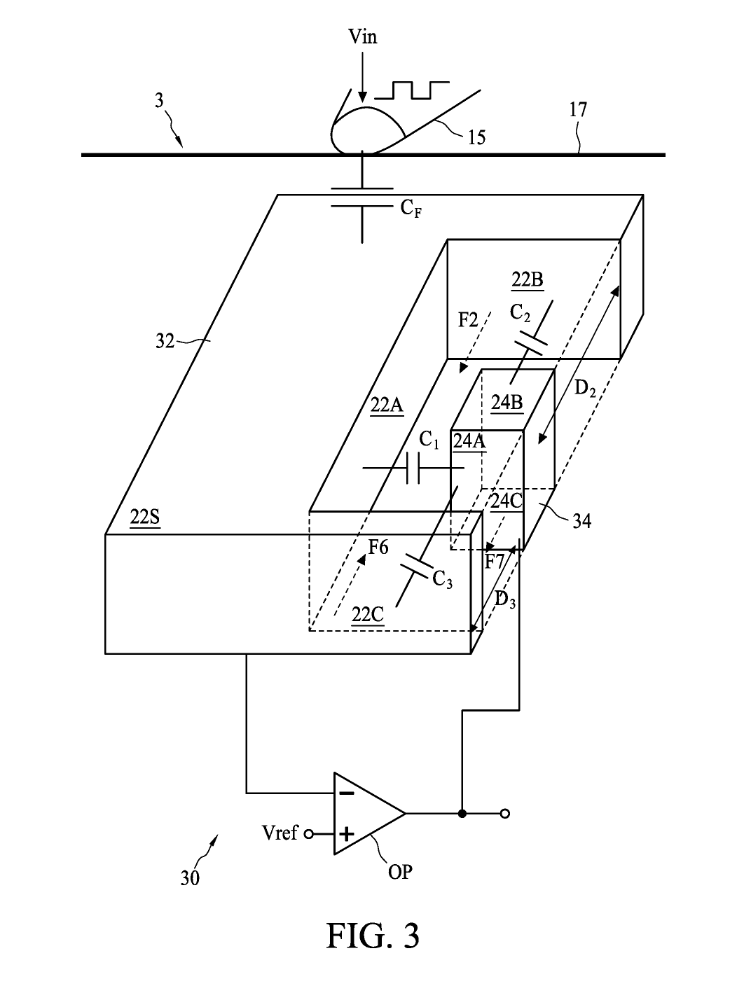

FIG. 3 is a diagram of a sensing device 3, in accordance with an exemplary embodiment of the present disclosure. Referring to FIG. 3, the sensing device 3 is similar to the sensing device 1 described and illustrated with reference to FIG. 2A except a sensing unit 30. The sensing unit 30 includes a first conductive component 32 and a second conductive component 34 formed in a first patterned conductive layer.

The first conductive component 32 is similar to the first conductive component 22 described and illustrated with reference to FIG. 2A except that, for example, the first conductive component 32 further includes a third sidewall 22C. The third sidewall 22C, assumed to be a planar surface, has a surface normal in a direction F6 substantially opposite to the normal direction F2.

The first sidewall 22A, the second sidewall 22B and the third sidewall 22C together define a recess. In the present embodiment, the second conductive component 34 is positioned in the recess. In some embodiments, a portion of the second conductive component 34 is positioned in the recess.

The second conductive component 34 is similar to the second conductive component 24 described and illustrated with reference to FIG. 2A except that, for example, the second conductive component 34 further includes a third sidewall 24C. The third sidewall 24C, assumed to be a planar surface, has a surface normal in a direction F7, substantially opposite to the normal direction F6. The normal direction F7 of the third sidewall 24C is substantially in parallel with the normal direction F2 of the second sidewall 22B of the second conductive component 34.

The third sidewall 24C is opposed to the third sidewall 22C of the first conductive component 32, and spaced apart from the third sidewall 22C of the first conductive component 32 by a distance D₃. The third sidewall 24C of the second conductive component 34 and the third sidewall 22C of the first conductive component 32 define a third capacitance C₃. Since the distance D₃ is a factor of the third capacitance C₃, by adjusting the distance D₃ in a layout design stage, the third capacitance C₃ is adjusted. The third capacitance C₃ decreases as the distance D₃ increases, and vice versa.

In operation, the sensing device 3 is configured to, in response to a touch event of the object 15 on the sensing device 3, detect a capacitance C_{F} in the normal direction F3. Specifically, in operation, the first conductive component 32 is configured to, in response to the touch event of the object 15 on the sensing device 1, detect the capacitance C_{F} in the normal direction F3. During the touch event, a trigger signal Vin is input to the sensing device 3 via the object 15, and is coupled to the second input terminal of the amplifier OP via the capacitor C_{F}. Moreover, during the touch event, an amplifier circuit is formed by the object 15, the first conductive component 32, the second conductive component 34 and the amplifier OP. A small-signal model for the amplifier circuit is similar to that for the amplifier circuit 25 illustrated and described with reference to FIG. 2B except that, for example, the third capacitor C₃ is taken into consideration. The first capacitor C₁, the second capacitor C₂ and the third capacitor C₃ are coupled in parallel with each other between the second input terminal and the output terminal of the amplifier OP. Accordingly, the relationship between the detection signal Vout and the trigger signal Vin can be expressed in an equation below.

$$\frac{Vout}{Vin} = - \frac{{C}_{F}}{( {C}_{1} + {C}_{2} + {C}_{3} )}$$

In the present embodiment, the second conductive component 34 is positioned in the recess. Since the first conductive component 32 and the second conductive component 34 form three pairs of opposed sidewalls (namely, the first sidewalls 22A and 24A, the second sidewalk 22B and 24B, and the third sidewalls 22C and 24C), given the sizes of the first conductive component 32 and the second conductive component 34 being kept unchanged, the touch sensitivity can be enhanced by adjusting the position of the second conductive component 24 in either the normal direction F₁ or F₂ without incurring area cost.

In some embodiments, a portion of the second conductive component 34 is positioned outside the recess. Assuming that that portion of the second conductive component 24 outside the recess 27 extends in the normal direction F₁, since the first conductive component 32 and the second conductive component 34 form three pairs of opposed sidewalls, given the sizes of the first conductive component 32 and the second conductive component 34 being kept unchanged, the touch sensitivity can be enhanced by adjusting the position of the second conductive component 34 in the normal direction F₂ without incurring area cost.

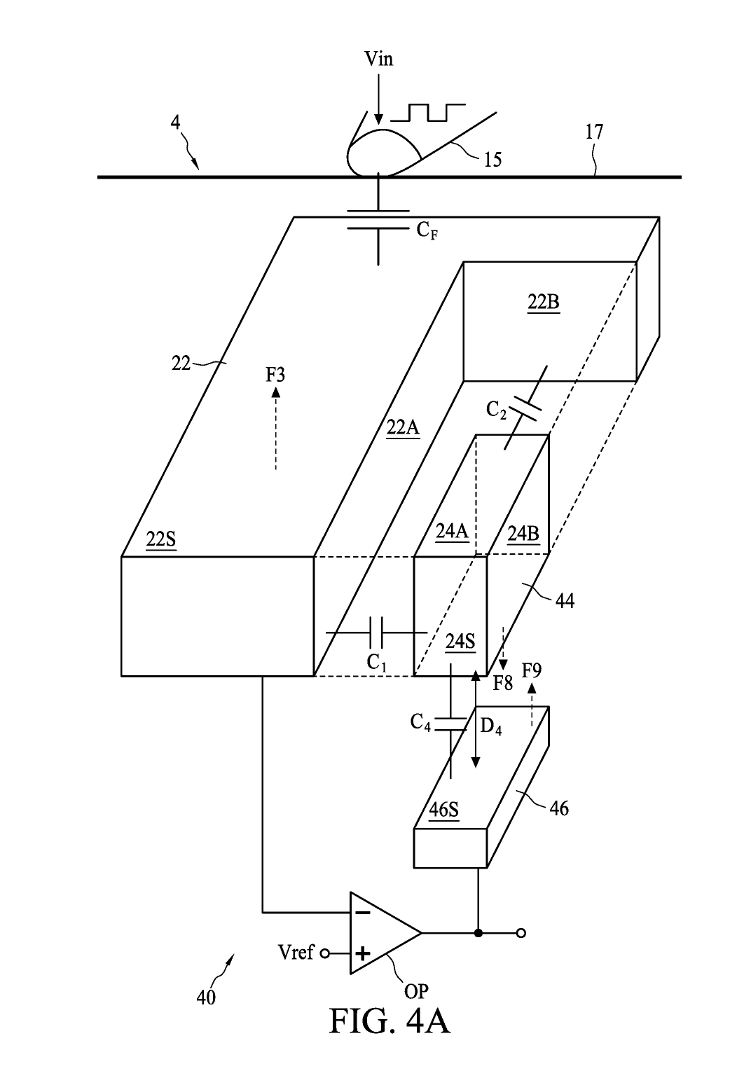

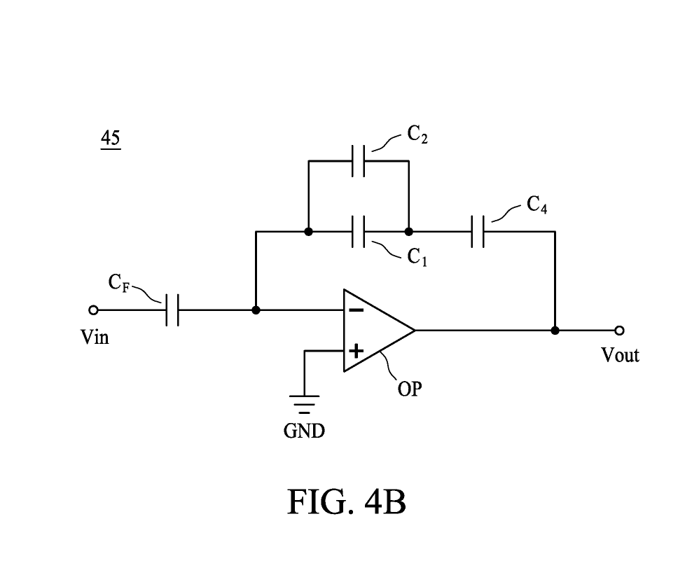

FIG. 4A is a diagram of a sensing device 4, in accordance with an exemplary embodiment of the present disclosure. Referring to FIG. 4A, the sensing device 4 is similar to the sensing device 1 described and illustrated with reference to FIG. 2A except that, for example, the sensing device 4 includes a second. conductive component 44 formed in a first patterned conductive layer, and a third conductive component 46 formed in a second patterned conductive layer. Moreover, the third conductive component 46 is coupled to the amplifier OP.

The second conductive component 44 and the third conductive component 46 are positioned in different patterned conductive layers. Moreover, the second conductive component 44 and the third conductive component 46 are separated by dielectric materials. In some embodiments, the second conductive component 44 and the third conductive component 46 are positioned in immediately adjacent patterned conductive layers, and are separated by a dielectric layer. In another embodiment, the second conductive component 44 and the third conductive component 46 are positioned in different patterned conductive layers spaced apart by a plurality of dielectric layers.

The second conductive component 44 is similar to the second conductive component 24 described and illustrated with reference to FIG. 2A except, for example, a surface 24S of the second conductive component 44. The surface 24S has a surface normal in a direction F8, substantially opposite to the normal direction F3.

The third conductive component 46 has a surface 46S. The surface 46S has a surface normal in a direction F9, substantially the same as the normal direction F3. Moreover, the surface 46S is opposed to the surface 24S of the second conductive component 44, and spaced apart from the surface 24S of the second conductive component 44 in the normal direction. F9 by a distance D₄. The surface 46S of the third conductive component 46 and the surface 24S of the second conductive component 44 define a fourth capacitance C₄. Since the distance D₄ is a factor of the fourth capacitance C₄, by adjusting the distance D₄ in a layout design stage, the fourth capacitance C₄ is adjusted. The fourth capacitance C₄ decreases as the distance D₄ increases, and vice versa.

In operation, the sensing device 4 is configured to, in response to a touch event of the object 15 on the sensing device 4, detect a capacitance C_{F} in the normal direction F3. Specifically, in operation, the first conductive component 22 is configured to, in response to the touch event of the object 15 on the sensing device 4, detect the capacitance C_{F} in the normal direction F3. During the touch event, a trigger signal Vin is input to the sensing device 1 via the object 15, and is coupled to the second input terminal of the amplifier OP via the capacitor C_{F}. Moreover, during the touch event, an amplifier circuit is formed by the object 15, the first conductive component 22, the second conductive component 44, the third conductive component 46 and the amplifier OP.

FIG. 4B is a circuit diagram of an amplifier circuit 45, in a small-signal mode, of the sensing device 4 as shown in FIG. 4A. The first capacitor C₁ and the second capacitor C₂ are coupled in parallel with each other between the second input terminal of the amplifier OP and the fourth capacitor C₄. Further, the first capacitor C₁ and the second capacitor C₂ are connected in parallel with respect to the capacitor C_{F} detected during the touch event. The parallel connected first capacitor C₁ and the second capacitor C₂ are serially connected with the fourth capacitor C₄ between the second input terminal and the output terminal of the amplifier OP. The amplifier OP receives the trigger signal Yin at the second. input terminal, amplifies the trigger signal Yin and outputs a detection signal Vout at the output terminal. The detection signal Vout is the amplified. trigger signal Yin. The relationship between the detection signal Vout and the trigger signal Vin can be expressed as the following equation (2).

$$\frac{Vout}{Vin} = - \frac{{C}_{F}}{\frac{( {C}_{1} + {C}_{2} ) \times {C}_{4}}{( {C}_{1} + {C}_{2} ) + {C}_{4}}} = - \frac{{C}_{F} \times [ ( {C}_{1} + {C}_{2} ) + {C}_{4} ]}{( {C}_{1} + {C}_{2} ) \times {C}_{4}} \qquad ( 2 )$$

where C₁ represents the first capacitance, C₂ represents the second capacitance C₂, and C_{F} represents the capacitance C_{F}. Moreover, the term (C₁+C₂)×C₄/(C₁+C₂)+C₄ represents an equivalent capacitance₂) between the second input terminal and the output terminal of the amplifier OP. Further, in equation (2), Vout represents a voltage value of the detection signal Vout, and Vin represents a voltage value of the trigger signal Vin. The voltage value of the detection signal Vout is substantially equal to the voltage value at the output terminal of the amplifier OP.

The absolute value of the ratio between the detection Vout and the trigger signal Yin represents a gain of the amplifier circuit 45. From the above equation (2), the gain of the amplifier circuit 45 is a function of the fourth capacitance C₄.

Furthermore, from the equation (2), the gain of the amplifier circuit 45 is a function of the equivalent capacitance between the second. input terminal and the output terminal of the amplifier OP.

Moreover, the voltage value at the output terminal of the amplifier OP is a function of the equivalent capacitance between the second. input terminal and the output terminal of the amplifier OP.

In the present embodiment, by introducing the fourth capacitor C₄, compared to the equation (1), the equivalent capacitance between the second input terminal and the output terminal of the amplifier OP is smaller. Therefore, the touch sensitivity in the present embodiment is better.

In some existing arrangements, a pair of electrode plates is adopted as a capacitive component between an input terminal and an output terminal of an amplifier. In that case, the capacitance can be decreased by decreasing the sizes of the electrode plates in order to enhance the touch sensitivity. However, such capacitive component with a relatively small capacitance is susceptible to noise during signal transmission. In contrast, instead of decreasing the sizes of conductive components to enhance the touch sensitivity, the sensing device 4 according to the present embodiments reduces the capacitance by arranging the conductive components in a fashion so that capacitances defined among the conductive components are connected in parallel. Effectively, the sensing device 4 is relatively robust to noise.

Moreover, given the sizes of the first conductive component 22 and the second conductive component 44 being kept unchanged, the touch sensitivity can be enhanced by adjusting the position of the second conductive component 44 in either the normal direction F₁ or F₂ without incurring area cost.

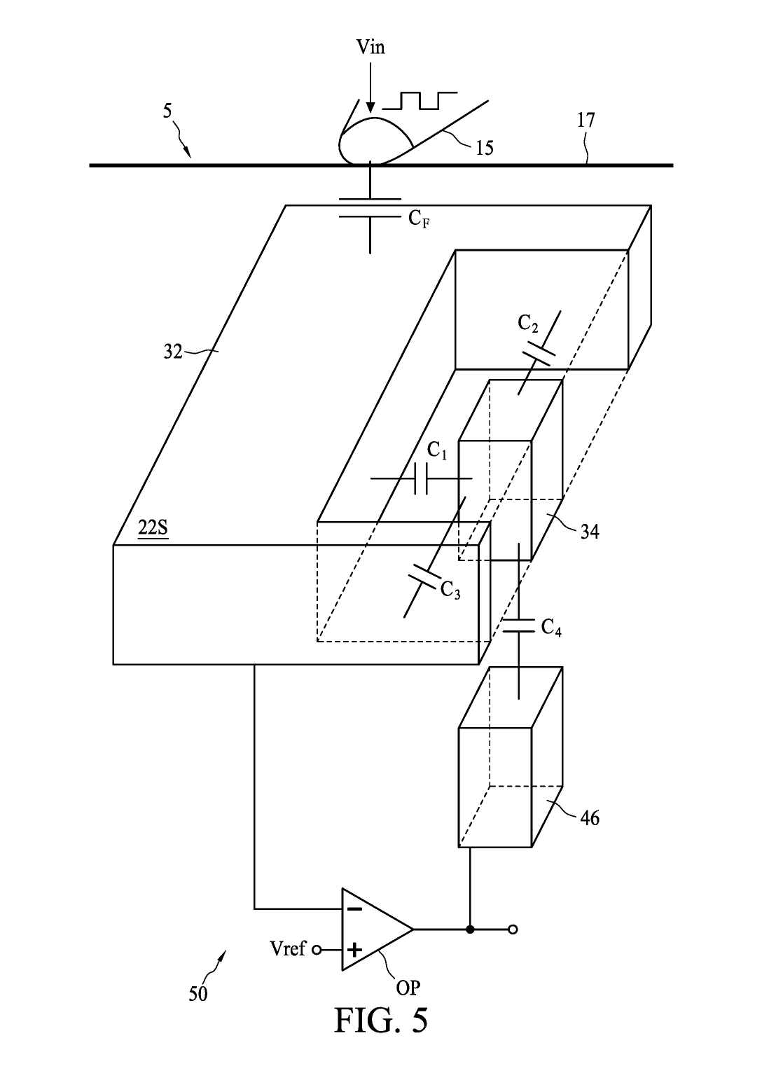

FIG. 5 is a diagram of a sensing device 5, in accordance with an exemplary embodiment of the present disclosure. The structure of the sensing device 5 is established based on the structure of the sensing device 3 illustrated and described with reference to FIG. 3, by further introducing the third conductive component 46 described and illustrated with reference to FIG. 4A. Therefore, for the illustrations similar to that described in the embodiments of FIG. 3 and FIG. 4A, the sensing device 5 in the present embodiments is relatively robust to noise. Moreover, given the sizes of the first conductive component 32 and the second conductive component 34 being kept unchanged, the touch sensitivity can be enhanced by adjusting the position of the second conductive component 34 in either the normal direction F₁ or F₂ without incurring area cost.

Although in language specific to structural features and/or methodological acts of the subject matter has been described, it is to be understood that the appended claims are not necessarily limited to the subject matter defined and the specific features or acts described above. Rather, the specific features and acts described above as exemplary forms of implementing the claims are disclosed.

Various operations of embodiments are provided herein. The order in which some or all of the operations are described should not be construed as to imply that these operations are necessarily order dependent. Alternative ordering will be appreciated given the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments.

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A sensing device for detecting a capacitance in response to a touch event of an object, the sensing device comprising:
a first conductive component, formed in a first patterned conductive layer, and having a first sidewall and a second sidewall;
a second conductive component, formed in the first patterned conductive layer, and having a first sidewall opposed to the first sidewall of the first conductive component, and a second sidewall opposed to the second sidewall of the first conductive component,
wherein the first sidewalk of the first conductive component and the second conductive component define a first capacitance therebetween, and the second sidewalk of the first conductive component and the second conductive component define a second capacitance therebetween.

2. The sensing device of claim 1, wherein the first capacitance and the second capacitance are connected in parallel with respect to the capacitance detected during the touch event.

3. The sensing device of claim 1, wherein the first sidewall and the second sidewall of the first conductive component form a recess, and at least a portion of the second conductive component is positioned in the recess.

4. The sensing device of claim 1, wherein the first capacitance and the second capacitance are connected in parallel between an input and an output of an amplifier.

5. The sensing device of claim 4, wherein an equivalent capacitance between the input and the output of the amplifier is equal to a sum of the first capacitance and the second capacitance.

6. The sensing device of claim 5, wherein a voltage value at the output of the amplifier is a function of the equivalent capacitance.

7. The sensing device of claim 6, wherein the voltage value at the output of the amplifier and the equivalent capacitance have a relationship as follows.
$$\frac{Vout}{Vin} = - \frac{{C}_{F}}{( {C}_{1} + {C}_{2} )}$$
where Vout represents the voltage value at the output of the amplifier, and Vin represents a voltage value of a trigger signal input to the sensing device, C₁ represents the first capacitance, C₂ represents the second capacitance, and C_{F} represents the capacitance detected during the touch event.

8. The sensing device of claim 1, wherein:
the first conductive component further includes a third sidewall, and
the second conductive component further includes a third sidewall opposed to the third sidewall of the first conductive component,
wherein the third sidewalls of the first conductive component and the second conductive component define a third capacitance therebetween.

9. The sensing device of claim 8, wherein a normal direction of the third sidewall of the second conductive component is in parallel with a normal direction of the second sidewall of the second conductive component.

10. The sensing device of claim 8, wherein the first sidewall, the second sidewall and the third sidewall of the first conductive component form a recess, and the second conductive component is positioned in the recess.

11. The sensing device of claim 8, wherein the first sidewall, the second sidewall and the third sidewall of the first conductive component form a recess, and a portion of the second conductive component is positioned outside the recess.

12. The sensing device of claim 8, wherein the first capacitance, the second capacitance and the third capacitance are coupled between an input and an output of an amplifier.

13. The sensing device of claim 1, wherein the second conductive component further includes a surface, and the sensing device further comprises:
a third conductive component, formed in a second patterned conductive layer different from the first patterned conductive layer, and includes a surface opposed to the surface of the second conductive component, wherein the surfaces of the third conductive component and the second conductive component define a fourth capacitance therebetween.

14. The sensing device of claim 13, wherein the first capacitance and the second capacitance are coupled in parallel between an input of an amplifier and the fourth capacitance, and the parallel connected first capacitance and second capacitance are serially connected with the fourth capacitance between the input and an output of the amplifier.

15. The sensing device of claim 14, wherein an equivalent capacitance between the input and the output of the amplifier is determined by the first capacitance and the second capacitance.

16. The sensing device of claim 15, wherein a voltage value at the output of the amplifier is a function of the equivalent capacitance.

17. The sensing device of claim 16, wherein the voltage value at the output of the amplifier and the equivalent capacitance have a relationship as follows.
$$\frac{Vout}{Vin} = - \frac{{C}_{F}}{\frac{( {C}_{1} + {C}_{2} ) \times {C}_{4}}{( {C}_{1} + {C}_{2} ) + {C}_{4}}} = - \frac{{C}_{F} \times [ ( {C}_{1} + {C}_{2} ) + {C}_{4} ]}{( {C}_{1} + {C}_{2} ) \times {C}_{4}}$$
where Vout represents the voltage value at the output of the amplifier, Vin represents a voltage value of a trigger signal input to the sensing device, C₁ represents the first capacitance, C₂ represents the second capacitance, C₄ represents the fourth capacitance, and C_{F} represents the capacitance detected during the touch event.

18. The sensing device of claim 8, wherein the second conductive component further includes a surface, and the sensing device further comprises:
a third conductive component, formed in a second patterned conductive layer different from the first patterned conductive layer, and includes a surface opposed to the surface of the second conductive component, wherein the surfaces of the third conductive component and the second conductive component define a fourth capacitance therebetween.

19. The sensing device of claim 18, wherein the first capacitance and the second capacitance are coupled in parallel between an input of an amplifier and the fourth capacitance, and the parallel connected first capacitance and second capacitance are serially connected with the fourth capacitance between the input and an output of the amplifier.
